(19) United States
(12) Patent Application Publication
(10) Pub. No.: US 2014/0115417 A1
(43) Pub. Date: Apr. 24, 2014

(54) ENCODING METHOD FOR QUASI-PERIODIC FADING CHANNEL

(71) Applicants: Eutelsat Sa, Paris (FR); Commissariat A L'energie Atomique Et Aux Ene Alt, Paris (FR)

(72) Inventors: Valentin SAVIN, Grenoble (FR); Lam PHAM SY, Cergy (FR)

(73) Assignees: Eutelsat Sa, Paris (FR); Commissariat A L'energie Atomique Et Aux Ene Alt, Paris (FR)

(21) Appl. No.: 14/057,134

(22) Filed: Oct. 18, 2013

(30) Foreign Application Priority Data
Oct. 19, 2012 (FR) 12 60002

(51) Int. Cl. H03M 13/29

(52) U.S. Cl. CPC H03M 13/2909
USPC 714/755

(57) ABSTRACT

The present invention relates to a method of error correction coding for a channel with quasi-periodic fade, such as the RSC (railroad satellite channel). According to an embodiment, it uses a block code (N, K) in which the parity check matrix comprises a sub-matrix obtained by horizontal concatenation of a plurality of identity matrices. The coding applies preferably to the level of the link layer, on data packets of the physical layer, without prior interleaving of said packets.

### TECHNICAL FIELD

The present invention relates in a general manner to the field of channel coding and more particularly coding adapted to a channel having quasi-periodic fade.

### PRIOR ART

Most current telecommunications systems use channel coding, also known as error correction coding or FEC (Forward Error Correction) to protect the data against the corruption that they can undergo during transmission on the channel. Among the types of corruption that can affect said data, transmission errors are generally distinguished from erasures. In the first case, the data are received with errors, due for example to an insufficient signal to noise ratio on the channel. In the second case, these data are purely and simply unavailable or unusable, following for example a fade or even a deep fade of the channel. One then speaks of an erasure channel.

We will consider hereafter the particular case of a transmission channel with quasi-periodic fade. Such a channel may be modelled by two states:
a first state referred to as “bad”, appearing in a quasi-periodic manner and of quasi-constant duration. Throughout the duration of this first state, the channel is affected by a fade and the data transmitted undergo an erasure;
a second state referred to as “good” during which the channel is simply noised. If needs be, during this second state, the data can undergo random erasure and of short duration compared to the duration of the erasure of the first state.

An example of channel with quasi-periodic fade is constituted of the transmission channel between a satellite and a train or RSC (railroad satellite channel) such as described particularly in the article of G. Siascia et al. entitled “Statistical characterization of the railroad satellite channel at Ku-band” published in Proceedings of the International Workshop of COST actions 272 and 280, May 2003. The RSC has a quite particular interest in the context of second generation Digital Video Broadcasting via Satellite or DVB-S2.

In the case of the aforementioned RSC, the state known as “bad” corresponds to the passage under power arches arranged at regular intervals along the railway track. In fact, when the antenna of a terminal passes underneath such a power arch the channel between the satellite and the terminal generally undergoes a deep fade.

The “good” state of the RSC corresponds on the other hand to the LOS (Line Of Sight) situation where the antenna of the terminal is in direct line of sight with the satellite. Short fades are mainly due to multi-path interference (Ricean fade).

In order to protect the transmitted data against quasi-periodic fading, several solutions have been proposed in the literature.

Firstly, it is possible to provide an error correction code with very long interleaving at the level of the physical layer. Nevertheless, this solution requires memories of very large size and complex and costly processing circuits.

Another better adapted solution is to provide an error correction coding at the level of the link layer (packets), as described for example in the article of B. Matuz et al. entitled “Link layer coding for DVB-S2 interactive satellite service to trains”, Vehicular Technology Conference, 2008, VTC Spring 2008, pp. 2922-2926, 11-14 May 2008, or instead at the level of the network layer (IP datagrams) as described in the article of S. Cioni et al. entitled “Advanced fade countermeasures for DVB-S2 systems in railway scenarios”, EURASIP Journal on Wireless Communications and Networking, 2007, Vol. 2007, pages 1-17.

Error correction coding at the level of the link layer does not however dispense with an interleaving between the physical layer and the link layer, in other words the packets must themselves be interleaved before being coded, which again requires complex circuits.

Error correction coding at the level of the network layer requires a complex segmentation and encapsulation method (GSE-FEC).

In both cases, these coding techniques do not make it possible to remedy long erasures of the RSC, particularly when a high speed train is obliged to slow down.

Finally, the correction codes used in the prior art are conventional block codings, poorly adapted to a periodic erasure scenario such as that of the RSC. In particular, these codes may have a low rate (fraction of the number of information symbols over the number of coded symbols) with regard to the probability of erasure.

The aim of the present invention is consequently to propose an error correction coding that overcomes the drawbacks of the prior art and in particular which does not require the realisation of a complex circuit/memory of large size and is particularly well adapted to a periodic erasure scenario.

### DESCRIPTION OF THE INVENTION

The present invention is defined as a method of error correction coding for a channel with quasi-periodic fade, said method coding a block of K information symbols into a block of N coded symbols, said quasi-periodic fade resulting in an erasure of at the most m consecutive coded symbols of said block, said method using a code (N, K) defined by a parity check matrix, H, of size (N−K)×N, the size N of the code satisfying N= n̅m and N<ρT where n̅ is an integer greater than or equal to 2, ρ is the transmission rate of the coded symbols and T being the period between consecutive fades of the channel, said parity check matrix comprising a sub-matrix, H=(Tₘ⁽¹⁾|Tₘ⁽²⁾ . . . |Tₘ^{( n̅)}), obtained by horizontal concatenation of n̅ triangular matrices Tₘ⁽ⁿ⁾, n=1, . . . , n̅ where the matrices Tₘ⁽ⁿ⁾, of size m×m, are all upper triangular or instead all lower triangular, and non-zero diagonal elements, the parity check matrix being defined to within one permutation of its lines.

The triangular matrices Tₘ⁽ⁿ⁾, n=1, . . . , n̅ may in particular all be identical, for example reduced to the identity matrix Iₘ.

According to a first embodiment, said parity check matrix H is constituted of said sub-matrix.

According to a second embodiment, the parity check matrix is obtained by vertical concatenation of an upper matrix, constituted of said sub-matrix, and of a lower matrix constituted of a sparse matrix of size l×N with l=M−m where M=N−K.

According to a third embodiment, the parity check matrix is obtained by vertical concatenation of an upper matrix, H_{U}, constituted of said sub-matrix, and of a lower matrix, H_{L}, itself constituted of the concatenation of a first sparse elementary matrix, H_{L}¹, of size l×K, of a second elementary matrix, H_{L}², triangular, of size l×l, of a third sparse elementary matrix, H_{L}³, of size l×(m−l), and of a fourth elementary matrix, H_{L}⁴, triangular, of size l×l and of zero diagonal, the matrices H_{L}², and H_{L}⁴, being of same nature, lower or upper, as the triangular matrices Tₘ⁽ⁿ⁾, n=1, . . . , n̅.

According to a first variant of the third embodiment, the parity check matrix is obtained by vertical concatenation of an upper matrix, H_{U}, constituted of said sub-matrix, and of a lower matrix, H_{L}, itself constituted of the concatenation of a first sparse elementary matrix, H_{L}¹, of size l×K, of a second elementary matrix, H_{L}², equal to a lower triangular matrix Tₗ, of size l×l, of a third sparse elementary matrix, H_{L}³, of size l×(m−l), and of a fourth elementary matrix, H_{L}⁴, of size l×l, only having non-zero elements below its diagonal.

According to a second variant of the third embodiment, the parity check matrix is obtained by vertical concatenation of an upper matrix, H_{U}, constituted of said sub-matrix, and of a lower matrix, H_{L}, itself constituted of the concatenation of a first sparse elementary matrix, H_{L}¹, of size l×K, of a second elementary matrix, H_{L}², equal to an upper triangular matrix Tₗ of size l×l, of a third sparse elementary matrix, H_{L}³, of size l×(m−l), and of a fourth elementary matrix, H_{L}⁴, of size l×l, only having non-zero elements above its diagonal.

The coding method may apply to the physical layer, said symbols then being bits.

Nevertheless, preferably, it will apply to the link layer, said information symbols then being data packets of the physical layer. More generally, it could apply to a layer of level n>2 in the OSI protocol, said information symbols being packets formed of data of the layer n−1.

### BRIEF DESCRIPTION OF DRAWINGS

FIG. 1 illustrates an application context of the method of error correction coding according to the present invention;

FIG. 2A represents the structure of a first parity check matrix used by the coding method according to a first embodiment of the invention;

FIG. 2B represents the structure of a first parity check matrix used by the coding method according to a more general version of the first embodiment of the invention;

FIG. 3 represents the structure of a second parity check matrix used by the coding method according to a second embodiment of the invention;

FIG. 4 represents the structure of a third parity check matrix used by the coding method according to a third embodiment of the invention;

FIG. 5 illustrates in a schematic manner the different steps of calculating parity symbols on the matrix of FIG. 4;

FIGS. 6A and 6B represent the symbol error rate at the level of the link layer when the coding method is implemented within the context of a transmission on RSC, for two train speeds respectively.

### DETAILED DESCRIPTION OF PARTICULAR EMBODIMENTS

We will consider hereafter a channel with quasi-periodic fade in the sense defined above, such as for example the RSC presented above.

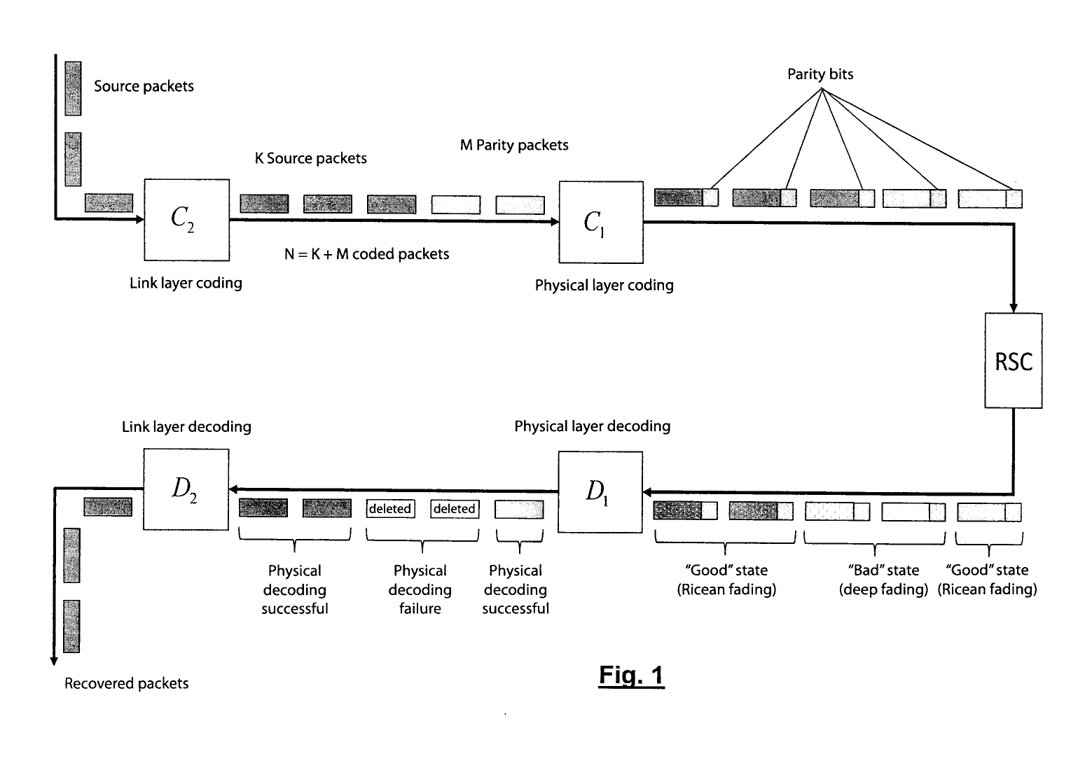

FIG. 1 represents an application context of the present invention.

The information symbols (bits for example) to be transmitted are grouped together in the form of packets, known as source packets, from an applicative layer. In the case of a DVB-S2 broadcast, for example, these packets are MPEG-TS (MPEG transport stream) packets.

These packets are preferably subject to an error correction coding at the level of the link layer (2^{nd} layer of the OSI model) in the encoder C₂. More precisely, the encoder C₁ codes a plurality K of incident packets P₁, . . . , P_{K} as source packets into a plurality N>K of coded packets. When the coding is systematic, this plurality of coded packets is constituted of source packets P₁, . . . , P_{K}, followed by M=N−K parity packets P_{K+1}, . . . , P_{N} (of same size as the source packets) representing the redundancy of the code. A parity packet is obtained as a sum, bit by bit, of several source packets, formalised by a parity check.

The packets P₁, . . . , P_{N} may then undergo a second error correction coding at the level of the physical layer (1^{st} layer of the OSI model) in the encoder C₁. More precisely, each packet Pₖ, k=1, . . . , K, of size q (q bits) is then coded in a packet P′ₖ of size q′>q. Here again, if the coding is systematic, the packet P′ₖ will be constituted of q initial bits and q′-q parity bits representing the redundancy of the code. It is also possible to group together several packets Pᵢ, . . . , Pⱼ into a super-packet, Pᵢ₋ⱼ and to apply the error correction coding to this super-packet. One then obtains a new packet, P′ᵢ₋ⱼ which, in the case of a systematic code, contains the bits of the super-packet, in other words all of the initial packets, Pᵢ, . . . , Pⱼ, as well as the parity bits corresponding to the redundancy of the code.

If needs be, an interleaving (not represented) may be provided at the packet level before the encoder C₂ and within each packet (or super-packet) before the encoder C₁.

In all cases, after transmission on the channel with periodic fade, the packets P′ₖ thereby coded are treated by the receiver as indicated hereafter.

At the level of the physical layer, each of the packets P′ₖ is decoded by the decoder D₁. If the decoding is successful, the packet Pₖ is transmitted to the link layer. On the other hand, if the decoding fails (for example, when the channel undergoes a fade) the packet Pₖ cannot be recovered and is considered as erased. The information of the erased packet is then transmitted to the link layer.

At the level of the link layer, each of the packets Pₖ is either correctly received, or considered as erased. The decoder D₂ then performs a decoding of the sequence of packets P₁, . . . , P_{N} in which one or more packets can be erased, to recover the initial packets P₁, . . . , P_{K}.

One will speak more specifically of channel with quasi-periodic erasure when, at the level of the link layer (or of an upper layer), the packets of this layer are periodically erased on account of periodic fades intervening at the level of the underlying physical layer. The term channel with periodic erasure will thus be consequently understood as a particular case of a channel with periodic fade.

The coding method according to the present invention is preferably implemented by the encoder C₂ and then applies to the aforementioned packets.

Alternatively, the coding method according to the present invention may be implemented by the encoder C₁ and then applies to the data of the physical layer (if needs be after interleaving).

Hereafter, in order to conserve a unitary presentation, we will designate by information symbols either data of the physical layer (bits for example) or packets of such data from the link layer (or instead of an upper layer). In all cases, the block of information symbols is noted s₁, . . . , s_{K} and the block of coded symbols is noted c₁, . . . , c_{N}. It will be understood that according to the envisaged level (physical, link or upper) the coded symbols are themselves data of the physical layer or packets of the link layer (or the upper layer).

Nevertheless it will be understood that, when the present invention is implemented at the level of the link layer, the decoding has simply to correct erasures of symbols (packets). One then speaks of an erasure decoding. In fact, the input of the decoder is constituted of the packets correctly decoded at the level of the physical layer. The fact that the packets have been correctly decoded may be verified for example by using a CRC code. The other packets (of which the decoding has failed) are considered as being erased.

When the coding method is implemented at the level of the physical layer, the receiver will use a conventional decoding of errors. The input of such a decoder is constituted of log likelihood ratios (LLRs), calculated from the signal observed at the output of the channel. When the channel goes through a fade, these LLRs have values very close to zero and may be considered as erasures, a LLR equal to zero signifying that one does not have any information on the value of the corresponding bit.

Whatever the level of implementation of the coding method, the size N of the code is chosen so that at the most one periodic fade (or bad state) of the channel intervenes during the transmission of a block of N coded symbols c₁, . . . , c_{N}. In other words, if one notes T the period of recurrence of the first state (bad state) of the channel, and ρ the output of the coded symbols, the size N will be chosen such that N<ρT.

One notes moreover τ the maximum duration of the fade of the channel, or in an equivalent manner the maximum duration of the first state. The maximum number of symbols erased, during the duration of this fade, is thus m=pτ.

The size N is chosen as a multiple of m, N= n̅m where n̅ is a whole number greater than or equal to 2, and satisfying N<ρT.

The coding method according to the invention uses a code per block (N, K) which may be conventionally defined by its generator matrix G of size K×N or by its parity check matrix H of size (N−K)×N.

It will be recalled that if s=(s₁, . . . , s_{K}) is the vector constituted of the information symbols, the associated code word c is given by the vector:

c=sG (1)

The words c of the code (N, K) satisfy:

cH^{T}=0 (2)

where .^{T} signifies the matrix transposition, the generator and parity check matrices being linked by the relation:

GH^{T}=0 (3)

Moreover, if the code is systematic, its generator matrix has the form:

G=(I_{K}|P) (4)

where I_{K} is the identity matrix of size K×K and P is the parity matrix of size K×(N−K). In this case, the parity check matrix is expressed as:

H=(P^{T}|I_{N-K}) (5)

where I_{N-K} is the identity matrix of size (N−K)×(N−K).

According to a first embodiment of the invention, one considers that the second state of the channel (good state) does not introduce errors (physical layer) or erasures (physical layer or link layer) in the information symbols. This situation intervenes in particular when the coding method applies to the link layer (the information symbols are then packets) and when the error correction coding (C₁) at the level of the physical layer is sufficiently efficient to correct the errors/erasures intervening in the second state of the channel.

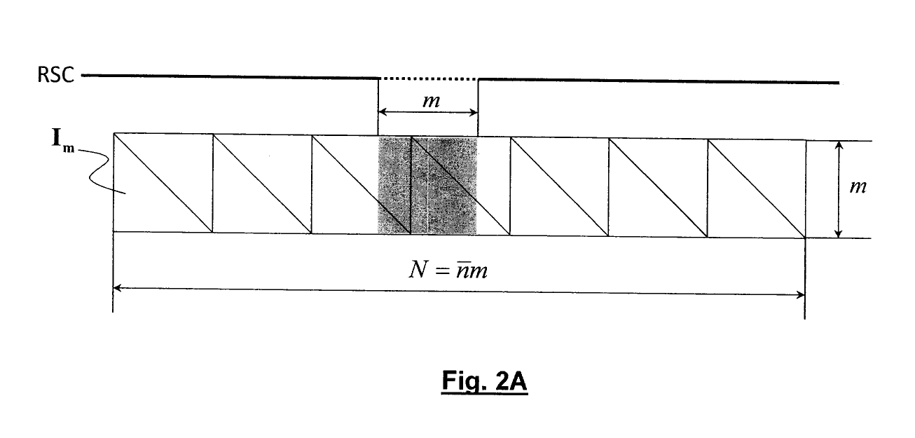

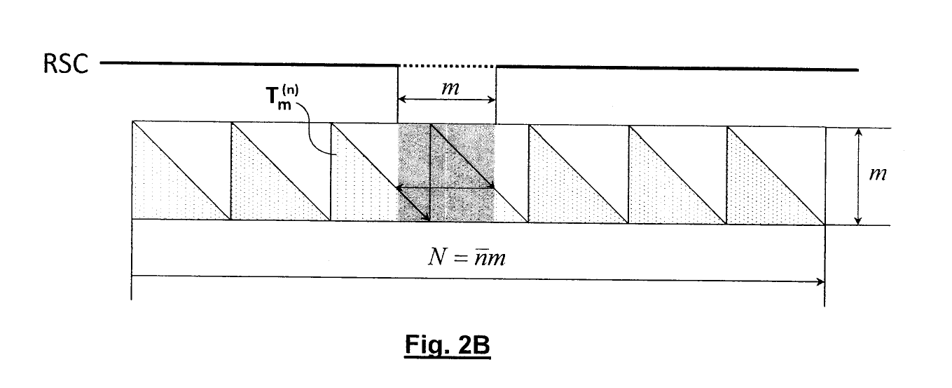

FIG. 2A represents in a schematic manner the structure of a parity check matrix used by the coding method according to the first embodiment of the invention.

It may be noted that this matrix is constituted of the concatenation of n̅=N/m identity matrices Iₘ of size m×m, i.e.:

H=(Iₘ|Iₘ . . . |Iₘ) (6)

The code is here systematic with N−m information symbols and m parity symbols since the parity matrix has the form of the expression (5). It will be assumed that the m parity symbols correspond to the final matrix Iₘ (the furthest on the right in FIG. 2).

Each line of the parity check matrix corresponds to a check and involves n̅ symbols ( n̅−1 information symbols and a parity symbol), the check being expressed as a XOR sum of these n̅ symbols. Given the particular structure of the parity check matrix, the different symbols intervening in a check i (line i) occupy the positions i, i+m, i+2, . . . , i+( n̅−1)m in the code word (in other words the columns having these indices in the matrix H).

When an erasure of length m (symbolised by a dotted line above the matrix) takes place, it only affects at the most m consecutive symbols of the code word. Thus, for a given parity check, i, the erasure will only affect at the most one symbol (in position j in the code word) since any preceding symbols (in positions j−m, j−2m, . . . ) and any following symbols (in positions j+m, j+2m, . . . ) intervening in this check are situated outside of the erasure zone. It is thus always possible to restore the erased symbol by means of the check in question.

According to a more general version represented in FIG. 2B, each identity matrix Iₘ appearing in (6) may be replaced by a triangular matrix (lower or upper), of size m×m i.e.:

H=(Tₘ⁽¹⁾|Tₘ⁽²⁾ . . . |Tₘ^{( n̅)} (7)

where the matrices Tₘ⁽ⁿ⁾, n=1, . . . , n̅ are triangular matrices (all lower or instead all upper) in which the diagonal elements are non-zero, in other words equal to 1. It will be recalled that an upper triangular matrix is a matrix in which the elements situated below the diagonal are all zero and that a lower triangular matrix is a matrix in which the elements situated above the diagonal are all zero.

According to this version, the parity matrix appears as a horizontal concatenation of matrices either all upper triangular or instead all lower triangular, and in which the diagonal elements are non-zero. It will be understood that this version is more general than the preceding version in so far as the identity matrix may be considered as a particular case of matrix Tₘ⁽ⁿ⁾.

In a particular example of embodiment, the triangular matrices Tₘ⁽ⁿ⁾, n=1, . . . , n̅ may all be identical, in other words: Tₘ⁽ⁿ⁾=Tₘ, ∀n.

It is also possible with the parity matrix structure given by the expression (7) to restore the erased symbols, thanks to the parity check, beginning with the first line containing an erased symbol and continuing by lines of increasing indices, if the triangular matrix is lower, or instead by beginning with the final line containing an erased symbol and by continuing with lines of decreasing indices, if the triangular matrix is upper. In fact, by proceeding in this way, each new line in the direction indicated by the arrows only contains one unknown symbol (erased), since the other symbols are situated either in the erasure zone but have already been restored by means of a preceding parity check (preceding line), or outside of the erasure zone.

The first variant (parity matrix given by the expression (6)) will be favoured when the coding method is implemented at the level of the link layer (or instead of an upper layer), whereas the second variant (parity matrix given by the expression (7)) will be favoured when the coding method is implemented at the level of the physical layer.

In fact, in the first case, the packets in the erasure zone are purely and simply absent (the CRC check at the level of the physical layer having declared them as erroneous), it is thus pointless to envisage a complex parity check. On the other hand, in the second case, certain bits of the erasure zone (bad state of the channel) may contain a useful information (non-zero LLR).

Finally, it will be understood that any permutation of the lines of the parity check matrix (7) conserves the preceding property, such a permutation only corresponding to a change of the order of the parity checks. In other words, the parity check matrix of the code could more generally result from the (horizontal) concatenation of n̅ matrices QₘTₘ⁽ⁿ⁾, where Qₘ is a permutation matrix of size m×m and where Tₘ⁽ⁿ⁾ has the same definition as previously.

H=(QₘTₘ⁽¹⁾)|QₘTₘ⁽²⁾ . . . |QₘTₘ^{( n̅)}) (8)

According to a second embodiment of the invention, one considers that errors and/or erasures of short duration may intervene on the channel when it is in its second state (good state).

Thus a code word may be affected either by a long erasure (of at the most m symbols) when the channel is in its first state during the transmission of the word, or by a short erasure and/or errors if the channel is in its second state during this transmission.

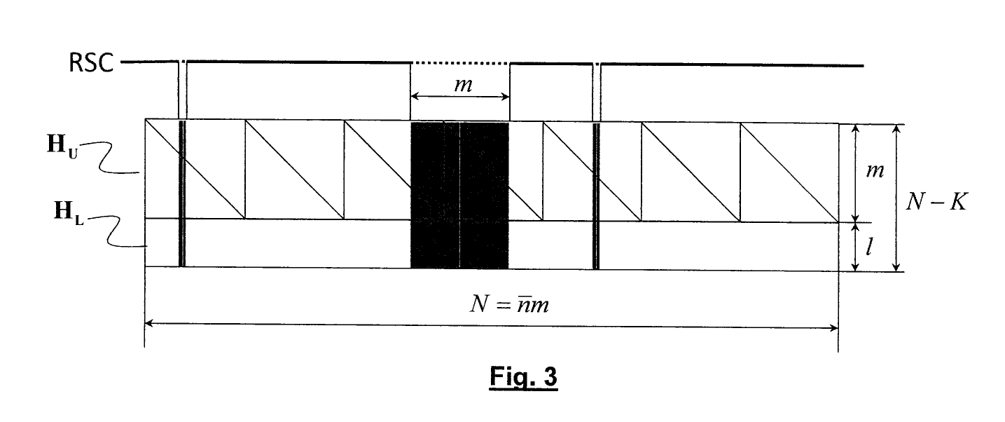

FIG. 3 represents in a schematic manner the structure of a parity check matrix used by the coding method according to the second embodiment of the invention.

It will be noted that the parity check matrix of the code (N, K) of FIG. 3 is constituted of the (vertical) concatenation of an upper matrix H_{U} of size m×N and of a lower matrix H_{L} of size l×N with l=M−m where M is the number of parity checks.

The upper matrix H_{U} is identical to the matrix H of the first embodiment. For example, the matrix H_{U} may be constituted of the (horizontal) concatenation of n̅ identity matrices Iₘ or of n̅ matrices QₘTₘ⁽ⁿ⁾.

The matrix H_{L} is a sparse matrix, in other words a matrix having for elements 0 values and several 1 values.

FIG. 3 (dotted lines) represents erasures that have taken place during the transmission of the code on the channel, namely a long erasure when the channel was in its first state and several short erasures (Rice fade) when the channel was in its second state.

The function of the upper matrix H_{U} is to enable the restitution of the symbols erased during a long erasure (first state). The function of the lower matrix H_{L} is to restore the symbols erased during short erasures and/or to correct the errors of the channel in the second state.

It will be understood that, as in the first embodiment, the parity check matrix is defined to within one permutation of its M=N−K lines.

The parity check matrix H represented in FIG. 3 nevertheless does not correspond to a systematic code. When a systematic coding is desired, the coding method described hereafter is advantageously implemented.

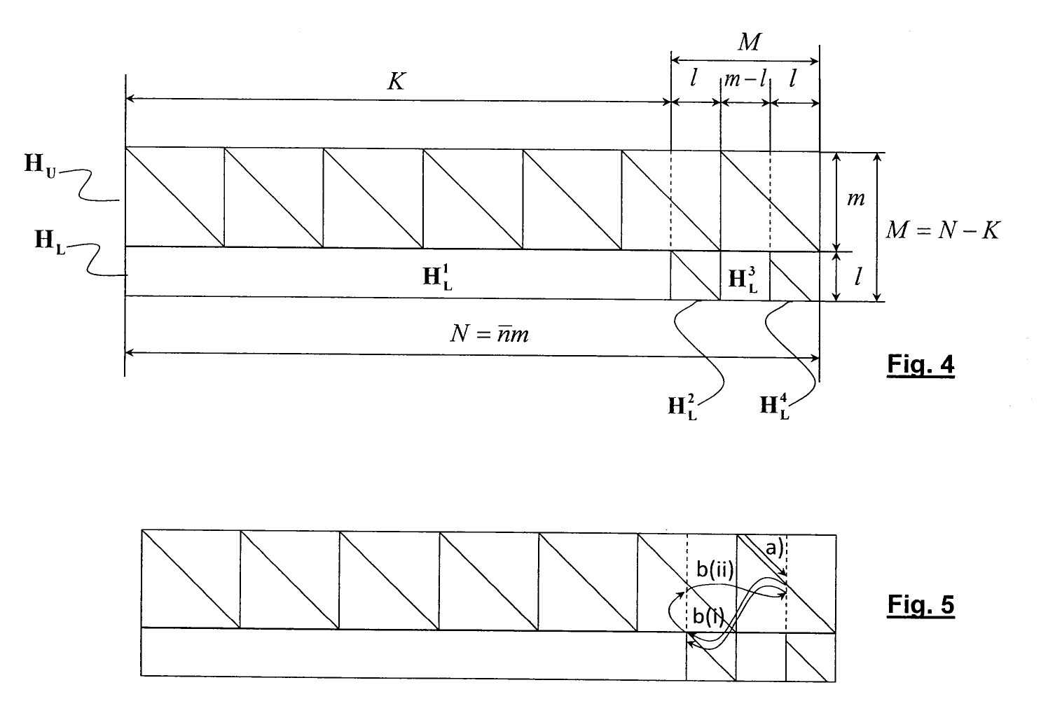

FIG. 4 represents in a schematic manner the structure of a parity check matrix of a code used by the coding method according to a third embodiment of the invention.

It may be noted that the parity check matrix H of the code (N, K) of FIG. 4 is constituted of the (vertical) concatenation of a first upper matrix H_{U} of size m×N and of a lower matrix H_{L} of size l×N with l=M−m where M=N−K is the number of parity checks.

The upper matrix H_{U} is constituted here of the (horizontal) concatenation of n̅ identity matrices Iₘ of size m×m.

The lower matrix H_{L} of size l×N is constituted of the (horizontal) concatenation of four elementary matrices, represented from left to right in FIG. 4:
a first sparse elementary matrix H_{L}¹ of size l×K;
a second elementary matrix H_{L}² equal to the identity matrix Iₗ of size l×l;
a third sparse elementary matrix H_{L}³ of size l×(m−l);
a fourth elementary matrix H_{L}⁴, sub-diagonal, of size l×l. Sub-diagonal matrix designates a matrix in which only the elements of the sub-diagonal are non-zero (in the present instance equal to 1).

The M last columns (on the right of FIG. 4) correspond to the parity symbols. These M parity symbols may be divided into three groups, noted p₁, p₂, p₃ of respective sizes l, m−l, l.

The code (N, K) is systematic since the K information symbols, s₁, . . . , s_{K}, are transmitted as such, the M=N−K parity symbols being calculated as follows:
a) the m/parity symbols of the group p₂ are firstly calculated from (XOR sum) information symbols intervening in the m−l first lines of the parity check matrix. More precisely, for the check i, the (l+i)^{th} parity symbol c_{K+l+i}, belonging to the group p₂, is obtained by the sum of the Ti information symbols:

c_{K+l+i}=sᵢ⊕sᵢ₊ₘ⊕ . . . ⊕s_{i+( n̅−1)m};
b) the parity symbols of the groups p₁ and p₃ are then determined recursively:
   i) the first parity symbol c_{K+1}, belonging to the group p₁ (the first of this group from the left in FIG. 4), is calculated as XOR sum of the information symbols appearing in the first line of the matrix H_{L}¹ and the parity symbols appearing in the first line of the matrix H_{L}³. In fact, these parity symbols belong to the group p₂ and have already been calculated at the step (a). It should be noted that due to the sub-diagonality of the matrix H_{L}⁴, the parity symbols of the group p₃ do not intervene;
   ii) the parity symbol c_{K+m+1} belonging to the group p₃ (the first of this group from the left in FIG. 4) is determined from n̅−1 information symbols intervening in the line m−l of H and from the first parity symbol obtained at the preceding step, namely:

c_{K+m+1}=sₘ₋ₗ₊₁⊕s₂ₘ₋ₗ₊₁⊕ . . . ⊕s_{( n̅−)m−l+1)}⊕c₁

One returns to the step (i) by estimating the second parity symbol c_{K+2}, belonging to the group p₁, as XOR sum of the information symbols appearing in the second line of the matrix H_{L}¹ and parity symbols appearing in the second line of the matrix H_{L}³ and of the parity symbol c_{K+m+1} that has just been calculated.

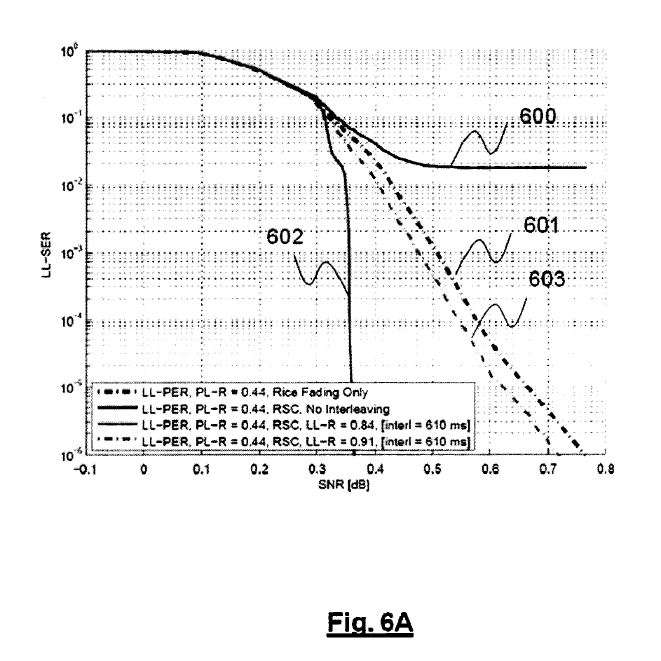

FIG. 5 illustrates in a schematic manner the different steps of calculating (a), (b)(i), (b)(ii) parity symbols during the coding of the parity symbols.

In the same way, the decoding is relatively simple since one can always come down to the restitution of an erasure/correction of an error by check line. Thus, the complexity of the decoding is linear as a function of the size N of the code.

According to a variant (not represented) of the third embodiment, one may use a code (N, K) defined by the parity check matrix H constituted of the (vertical) concatenation of an upper matrix H_{U} of size m×N and of a lower matrix H_{L} of size l×N, the upper matrix H_{U} being obtained by horizontal concatenation of n̅ matrices QₘTₘ⁽ⁿ⁾ as in the expression (8), Qₘ being a permutation matrix and the matrices Tₘ⁽ⁿ⁾ being triangular matrices (all lower or instead all upper, and non-zero diagonal elements), the lower matrix H_{L} being constituted of the horizontal concatenation of four elementary matrices, H_{L}¹, H_{L}², H_{L}³, H_{L}⁴, the first and third elementary matrices H_{L}¹ and H_{L}³ being identical to those described previously, the second elementary matrix H_{L}² being triangular and of same nature as Tₘ (lower or upper) and the fourth elementary matrix H_{L}⁴ only having non-zero elements below or above its diagonal (and thus zero elements on its diagonal), depending on whether Tₘ is lower or upper triangular.

It is also possible, according to this variant, to calculate firstly the parity symbols of the group p₂, then by successive iterations those of the groups p₁ and p₃.

As in the preceding embodiments, the matrix of the parity code is defined to within one permutation of its lines, a permutation of the lines equivalent to a permutation of the parity checks.

Whatever the embodiment envisaged, the code (N, K) defined by the parity matrices given above is well adapted to a channel with erasure periodic and has a minimum redundancy.

When the coding method of the invention is applied at the link level, a prior interleaving of the packets is not necessary, and the latency is not affected, which is particularly important for services in streaming mode.

It also ensues that the corresponding coding circuit does not require important memory resources.

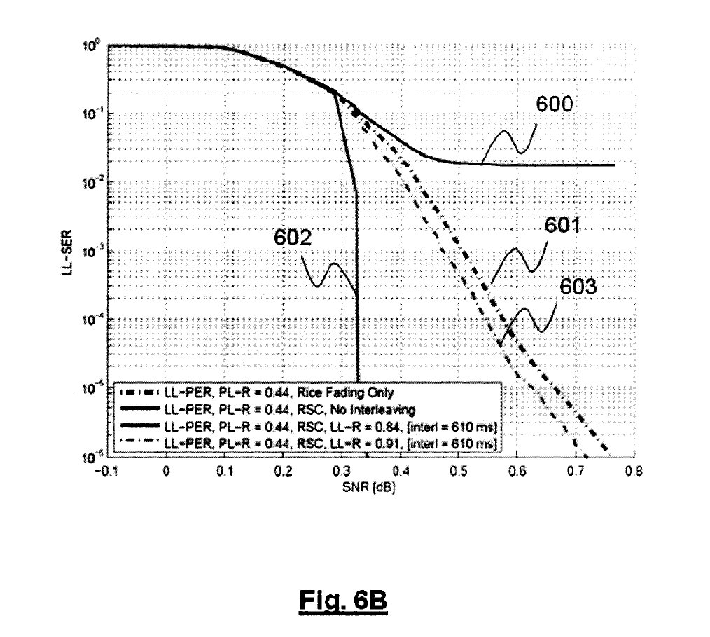

FIGS. 6A and 6B represent the symbol error rate at the level of the link layer, in other words the packet error rate when the coding method is implemented within the context of a transmission on RSC.

The distance between the power arches, on which depends the period of the erasure of the RSC in the first state, has been taken equal to 50 m. The width of the power arch in the axis of movement of the train, on which depends the duration of the periodic erasure, has been taken equal to 87 cm. The probability that a symbol undergoes an erasure at the level of the physical layer (due to a deep fade) is none other than the ratio between the width of the power arch and the distance between power arches, namely 1.54 10⁻².

It is assumed that the communication between the satellite and the terminal obeys the DVB-S2 standard with a QPSK modulation, a modulation speed of 27.5 Mbaud, an FEC code (at the level of the physical layer) of length 16200 bits and output 4/9.

In the examples illustrated, the coding method according to the present invention has been applied to the level of the link layer, the information symbols being MPEG-TS packets of 188 octets. The dimensions of the code were N=9064; m=824; l=626 (and thus M=1450).

FIGS. 6A and 6B correspond to a train speed of 60 km/h and 300 km/h, respectively.

In the two figures, the solid curve in solid line 600 represents the packet error rate as a function of the signal to noise ratio (SNR) of the RSC (periodic deep fade and random fade of Rice type). The curve in broken line 601 represents the packet error rate in the absence of periodic fades (random fade of Rice type only, in other words channel constantly in the second state).

The curve 603 represents the packet error rate on the RSC after the coding according to the first embodiment, thus with an output of (N−m)/N=0.91.

It may be noted that the application of the coding method makes it possible to eliminate completely the deterioration of the packet error rate (more precisely to delete the lower limit of the packet error rate) due to periodic erasure (even at low speed, cf. FIG. 6A) since, in the two figures, curve 603 has the same slope as curve 601.

Curve 602 represents the packet error rate on this same RSC, after coding according to the third embodiment, thus with an output if (N−m−l)/N=0.84. It will be noted that the l parity symbols/parity checks added make it possible to reduce in a significant manner the residual errors/erasures appearing in the second state of the channel.

1. A method of error correction coding in a channel with quasi-periodic fade, said method coding a block of K information symbols in a block of N coded symbols intended to be transmitted on said channel, said quasi-periodic fade resulting in an erasure of at the most m consecutive coded symbols of said block, said method using a code (N, K) defined by a parity check matrix, H, of size (N−K)×N, and wherein the size N of the code satisfies N= n̅m and N<ρT where n̅ is an integer greater than or equal to 2, ρ is the transmission rate of the coded symbols and T being the period between consecutive fades of the channel, said parity check matrix being obtained by vertical concatenation of an upper matrix H_{U} and of a lower matrix, H_{L}, said upper matrix H_{U}=(Tₘ⁽¹⁾|Tₘ⁽²⁾ . . . |Tₘ^{( n̅)}) being obtained by horizontal concatenation of n̅ triangular matrices Tₘ⁽ⁿ⁾, n=1, . . . , n̅ where the matrices Tₘ⁽ⁿ⁾, of size m×m, are all upper triangular or instead all lower triangular, and non-zero diagonal elements, said lower matrix being constituted of the concatenation of a first sparse elementary matrix, H_{L}¹, of size l×K, of a second elementary matrix, H_{L}², triangular, of size l×l, of a third sparse elementary matrix, H_{L}³, of size l×(m−l), and of a fourth elementary matrix, H_{L}⁴, triangular, of size l×l and of zero diagonal, the matrices H_{L}² and H_{L}⁴ being of same nature, lower or upper, as the triangular matrices Tₘ⁽ⁿ⁾, n=1, . . . , n̅, the parity check matrix being defined to within one permutation of its lines, and the order of the columns of the parity check matrix corresponding to the order of transmission of the coded symbols on said channel.

2. A coding method according to claim 1, wherein the triangular matrices Tₘ⁽ⁿ⁾, n=1, . . . , n̅ are all identical.

3. A coding method according to claim 2, wherein the triangular matrices Tₘ⁽ⁿ⁾, n=1, . . . , n̅ are reduced to the identity matrix Iₘ.

4. A coding method according to claim 3, wherein the second elementary matrix, H_{L}², is a lower triangular matrix Tₗ, and that the fourth elementary matrix, H_{L}⁴, only has non-zero elements below its diagonal.

5. A coding method according to claim 2, wherein the second elementary matrix, H_{L}², is an upper triangular matrix Tₗ of size l×l, and that the fourth elementary matrix, H_{L}⁴, of size l×l, only has non-zero elements above its diagonal.

6. A coding method according to claim 1, further comprising applying said method to a physical layer, said symbols then being bits.

7. A coding method according to claim 1, further comprising applying said method to a link layer, said information symbols being data packets of a physical layer.

8. A coding method according to claim 1, further comprising applying said method to a layer of level n>2 in the OSI protocol, said information symbols being packets formed by data of the layer n−1.
